(19) United States
(12) Patent Application Publication
(10) Pub. No.: US 2007/0183189 A1
(43) Pub. Date: Aug. 9, 2007

(54) Memory having nanotube transistor access device

(76) Inventors: Thomas Nirschl, Loiching (DE); Ronald Kakoschke, Munchen (DE)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/350,191

(22) Filed: Feb. 8, 2006

(51) Int. Cl. G11C 11/00

(52) U.S. Cl. 365/163

(57) ABSTRACT

A memory cell includes a memory element and a nanotube transistor contacting the memory element for accessing the memory element.

### BACKGROUND

One type of non-volatile memory is resistive memory. Resistive memory utilizes the resistance value of a memory element to store one or more bits of data. For example, a memory element programmed to have a high resistance value may represent a logic “1” data bit value, and a memory element programmed to have a low resistance value may represent a logic “0” data bit value. The resistance value of the memory element is switched electrically by applying a voltage pulse or a current pulse to the memory element. One type of resistive memory is phase-change memory. Phase-change memory uses a phase-change material for the resistive memory element.

Phase-change memories are based on phase-change materials that exhibit at least two different states. Phase-change material may be used in memory cells to store bits of data. The states of phase-change material may be referred to as amorphous and crystalline states. The states may be distinguished because the amorphous state generally exhibits higher resistivity than does the crystalline state. Generally, the amorphous state involves a more disordered atomic structure, while the crystalline state involves a more ordered lattice. Some phase-change materials exhibit more than one crystalline state, e.g. a face-centered cubic (FCC) state and a hexagonal closest packing (HCP) state. These two crystalline states have different resistivities and may be used to store bits of data.

Phase change in the phase-change materials may be induced reversibly. In this way, the memory may change from the amorphous state to the crystalline state and from the crystalline state to the amorphous state in response to temperature changes. The temperature changes to the phase-change material may be achieved in a variety of ways. For example, a laser can be directed to the phase-change material, current may be driven through the phase-change material, or current can be fed through a resistive heater adjacent the phase-change material. In any of these methods, controllable heating of the phase-change material causes controllable phase change within the phase-change material.

A phase-change memory including a memory array having a plurality of memory cells that are made of phase-change material may be programmed to store data utilizing the memory states of the phase-change material. One way to read and write data in such a phase-change memory device is to control a current and/or a voltage pulse that is applied to the phase-change material. The level of current and/or voltage generally corresponds to the temperature induced within the phase-change material in each memory cell.

The current used to change (set or reset) the phase-change element in a phase-change memory cell from one state to another state strongly depends on the current density at the interface between the electrode and the phase-change element. Spacer techniques have been used to reduce the interface area, which reduces the absolute current needed to set and reset the memory element. Another technique used to reduce the interface area uses a nanowire electrode for the phase-change memory cell as described in U.S. patent application Ser. No. 11/182,022 entitled “PHASE CHANGE MEMORY CELL HAVING NANOWIRE ELECTRODE”, filed Jul. 14, 2005. The memory cell size in these techniques, however, is still limited by the access device used to drive the current through the phase-change element.

In addition, to set and reset the phase-change element, the threshold voltage of the phase-change element has to be provided, hence, the resistance of the access device has to be small enough to enable low voltage operation. Further, phase-change memory cells are typically backend-of-line memory cells. Thus, a substantial amount of area is used to connect the access devices, usually located in the front-end-of-line, to the memory cells located in the backend-of-line.

### SUMMARY

One embodiment of the present invention provides a memory cell. The memory cell includes a memory element and a nanotube transistor contacting the memory element for accessing the memory element.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a memory device.

FIG. 2 is a diagram illustrating one embodiment of a carbon nanotube (CNT) transistor.

FIG. 3A is a diagram illustrating one embodiment of a memory cell.

FIG. 3B is a diagram illustrating another embodiment of a memory cell.

FIG. 4A is a diagram illustrating one embodiment of a pair of memory cells.

FIG. 4B is a diagram illustrating another embodiment of a pair of memory cells.

FIG. 4C is a diagram illustrating another embodiment of a pair of memory cells.

FIG. 5 is a diagram illustrating another embodiment of a memory cell.

FIG. 6 is a diagram illustrating another embodiment of a pair of memory cells.

FIG. 7 is a diagram illustrating another embodiment of a pair of memory cells.

### DETAILED DESCRIPTION

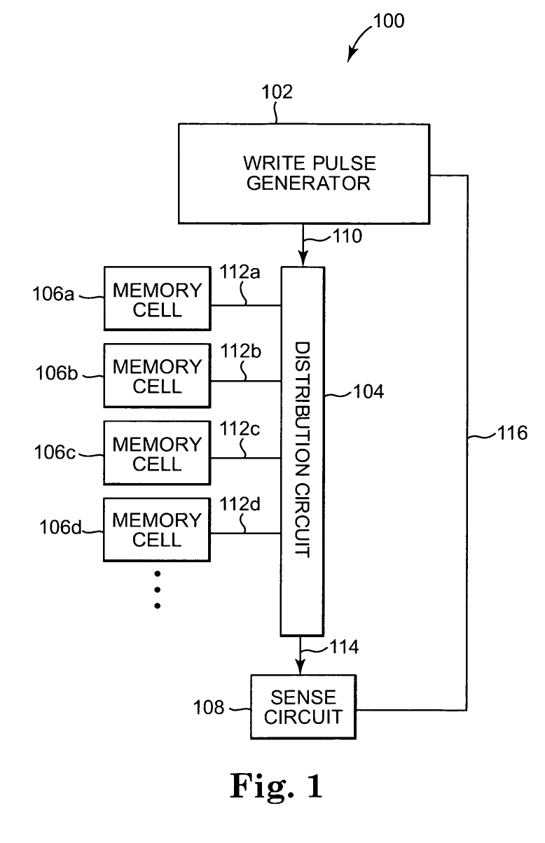

FIG. 1 is a block diagram illustrating one embodiment of a memory device 100. Memory device 100 includes a write pulse generator 102, a distribution circuit 104, memory cells 106a, 106b, 106c, and 106d, and a sense circuit 108. In one embodiment, memory cells 106a-106d are resistive memory cells, such as phase-change memory cells that are based on the amorphous to crystalline phase transition of the memory material in the memory cell. In another embodiment, memory cells 106a-106d are conductive bridging random access memory (CBRAM) cells, magneto-resistive random access memory (MRAM) cells, ferro-electric random access memory (FeRAM) cells, cantilever memory cells, polymer memory cells, or other suitable backend-of-line memory cells.

Each memory cell 106a-106d includes a memory element and a nanotube transistor for accessing the memory element. In one embodiment, the nanotube transistor is a carbon nanotube (CNT) transistor. The CNT transistor is placed between two metallization layers. The current density of a CNT transistor is much higher than the current density of a metal-oxide-semiconductor field effect transistor (MOSFET). The memory element, such as a phase-change element, is electrically coupled to the nanotube transistor. In one embodiment, the memory element is in a mushroom configuration and contacts the source or drain of the nanotube transistor. In another embodiment, the phase-change element is located inside a via in which the nanotube transistor is also located and contacts the source or drain of the nanotube transistor.

The area of the nanotube transistor based memory cell according to the present invention is scalable to 4F², where “F” is the minimum feature size. The small area occupied by each memory cell enables embedded and stand alone memory circuits. In addition, due to the larger current density of the CNT transistor compared to MOSFETs, the core requirements for the peripheral circuitry for accessing the memory cells are relaxed. The core requirements for the peripheral circuitry are relaxed since the voltage drop across a CNT transistor is small compared to the voltage drop across a MOSFET. Due to the smaller size of the memory cell, the interconnect length is also reduced, which further reduces the parasitic resistance and capacitance (RC) constant. Thus, the CNT transistor memory cell enables scaling of the memory cell to 4F².

The CNT transistor is placed as close as possible to the memory element. Wiring and parasitic effects are minimized as the memory element does not need a connection down to the silicon surface. The incorporation of the memory element is not limited to only one layer; rather several of the memory elements may be stacked. The current density at the interface between the CNT transistor selection device and the phase-change element is inherently increased, which helps to reduce the set and reset currents. For embedded memory circuits where several metallization levels are available, the integration of a memory array into upper levels of metallization with decoder and control logic integrated just below the memory array is feasible. The lower metallization level, however, may also be realized as highly doped silicon or polysilicon if there are not enough metallization levels available (e.g., for stand alone memory circuits the amount of metallization levels may be limited).

In one embodiment, write pulse generator 102 generates current or voltage pulses that are controllably directed to memory cells 106a-106d via distribution circuit 104. In one embodiment, distribution circuit 104 includes a plurality of transistors that controllably direct current or voltage pulses to the memory cells. Write pulse generator 102 is electrically coupled to distribution circuit 104 through signal path 110. Distribution circuit 104 is electrically coupled to each of the memory cells 106a-106d through signal paths 112a-112d. Distribution circuit 104 is electrically coupled to memory cell 106a through signal path 112a. Distribution circuit 104 is electrically coupled to memory cell 106b through signal path 112b. Distribution circuit 104 is electrically coupled to memory cell 106c through signal path 112c. Distribution 104 is electrically coupled to memory cell 106d through signal path 112d. In addition, distribution circuit 104 is electrically coupled to sense circuit 108 through signal path 114, and sense circuit 108 is electrically coupled to write pulse generator 102 through signal path 116.

Sense circuit 108 senses the state of the memory cells 106a-106d and provides signals that indicate the state of the resistance of the memory cells 106a-106d. Sense circuit 108 reads each state of memory cells 106a-106d through signal path 114. Distribution circuit 104 controllably directs read signals between sense circuit 108 and memory cells 106a-106d through signal paths 112a-112d. In one embodiment, distribution circuit 104 includes a plurality of transistors that controllably direct read signals between sense circuit 108 and memory cells 106a-106d.

In one embodiment, memory cells 106a-106d are made of a phase-change material that may be changed from an amorphous state to a crystalline state or from a crystalline state to an amorphous state under influence of temperature change. The degree of crystallinity thereby defines at least two memory states for storing data within memory device 100. The at least two memory states can be assigned to the bit values “0” and “1”. The bit states of memory cells 106a-106d differ significantly in their electrical resistivity. In the amorphous state, a phase-change material exhibits significantly higher resistivity than in the crystalline state. In this way, sense amplifier 108 reads the cell resistance such that the bit value assigned to a particular memory cell 106a-106d is determined.

To program a memory cell 106a-106d within memory device 100, write pulse generator 102 generates a current or voltage pulse for heating the phase-change material in the target memory cell. In one embodiment, write pulse generator 102 generates an appropriate current or voltage pulse, which is fed into distribution circuit 104 and distributed to the appropriate target memory cell 106a-106d. The current or voltage pulse amplitude and duration is controlled depending on whether the memory cell is being set or reset. Generally, a “set” operation of a memory cell is heating the phase-change material of the target memory cell above its crystallization temperature (but below its melting temperature) long enough to achieve the crystalline state. Generally, a “reset” operation of a memory cell is heating the phase-change material of the target memory cell above its melting temperature, and then quickly quench cooling the material, thereby achieving the amorphous state.

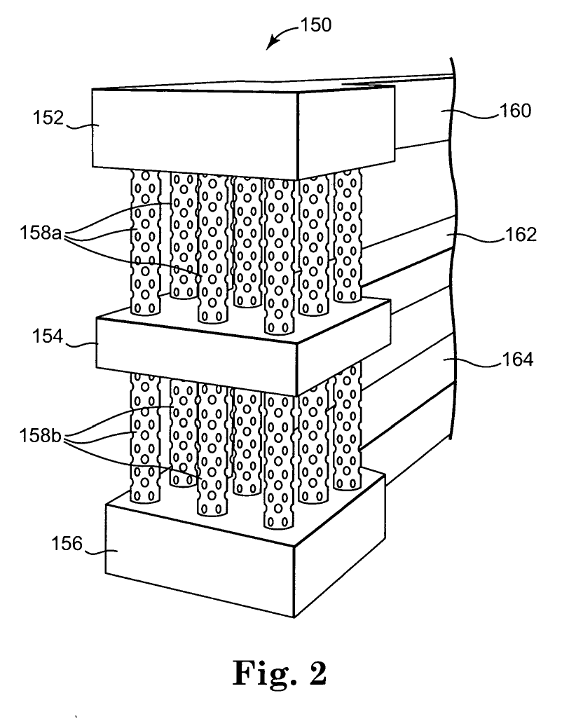

FIG. 2 is a diagram illustrating one embodiment of a nanotube transistor 150. In one embodiment, nanotube transistor 150 is a carbon nanotube (CNT) transistor. CNT transistor 150 includes a first metal layer 152, a gate layer 154, a second metal layer 156, and nanotubes 158a and 158b. First metal layer 152 provides one of the source and drain for CNT transistor 150, and second metal layer 156 provides the other one of the source and drain for CNT transistor 150. First metal layer 152 is electrically coupled to a first conductive line 160, which provides a source line or a drain line. Gate layer 154 is electrically coupled to a word line 162. Second metal layer 156 is electrically coupled to a second conductive line 164, which provides a source line or a drain line. First metal layer 152 is electrically coupled to one side of nanotubes 158a. The other side of nanotubes 158a are electrically coupled to one side of gate layer 154. The other side of gate layer 154 is electrically coupled to one side of nanotubes 158b. The other side of nanotubes 158b are electrically coupled to second metal layer 156.

In response to a logic high signal on word line 162, CNT transistor 150 turns on to pass signals between first conductive line 160 and second conductive line 164. In response to a logic low signal on word line 162, CNT transistor 150 turns off to block signals from passing between first conductive line 160 and second conductive line 164. CNT transistor 150 has a larger current density than a metal-oxide-semiconductor field effect transistor (MOSFET).

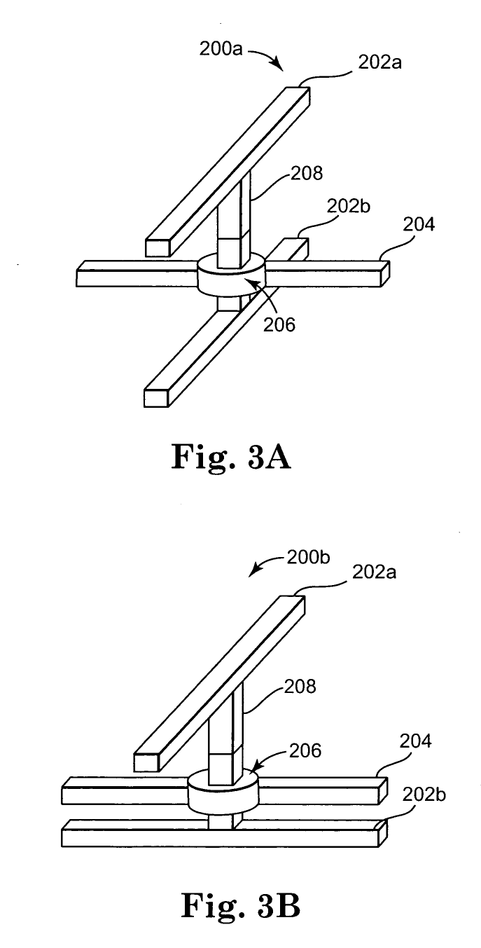

FIG. 3A is a diagram illustrating one embodiment of a memory cell 200a. In one embodiment, each memory cell 106a-106d is similar to memory cell 200a. Memory cell 200a includes a first conductive line 202a, a word line 204, a second conductive line 202b, a CNT transistor 206, and a phase-change element 208. First conductive line 202a is electrically coupled to one side of phase-change element 208. The other side of phase-change element 208 is electrically coupled to one side of the source-drain path of CNT transistor 206. The other side of the source-drain path of CNT transistor 206 is electrically coupled to second conductive line 202b. The gate of CNT transistor 206 is electrically coupled to word line 204.

In one embodiment, first conductive line 202a is a source line and second conductive line 202b is a bit line. In another embodiment, first conductive line 202a is a bit line and second conductive line 202b is a source line. First conductive line 202a is located in a first horizontal plane, word line 204 is located in a second horizontal plane, and second conductive line 202b is located in a third horizontal plane. The first horizontal plane is spaced apart from and parallel to the second horizontal plane, and the second horizontal plane is spaced apart from and parallel to the third horizontal plane. Phase-change element 208 extends from first conductive line 202a toward word line 204. The source-drain path of CNT transistor 204 extends from word line 204 toward first conductive line 202a and toward third conductive line 206. Phase-change element 208 and the source-drain path of CNT transistor 206 are substantially aligned vertically.

In one embodiment, first conductive line 202a is substantially parallel to second conductive line 202b, and word line 204 is substantially perpendicular to first conductive line 202a and second conductive line 202b. In another embodiment, word line 204 is at an angle other than 90° to first conductive line 202a and second conductive line 202b.

Phase-change element 208 is fabricated within the same via in which CNT transistor 206 is fabricated. Phase-change element 208 may be made up of a variety of materials in accordance with the present invention. Generally, chalcogenide alloys that contain one or more elements from group VI of the periodic table are useful as such materials. In one embodiment, phase-change element 208 of memory cell 200a is made up of a chalcogenide compound material, such as GeSbTe, SbTe, GeTe, or AgInSbTe. In another embodiment, phase-change element 208 is chalcogen free, such as GeSb, GaSb, InSb, or GeGaInSb. In other embodiments, phase-change element 208 is made up of any suitable material including one or more of the elements Ge, Sb, Te, Ga, As, In, Se, and S.

In response to a logic high signal on word line 204, CNT transistor 206 is turned on to pass a signal from first conductive line 202a through phase-change element 208 to second conductive line 202b, or pass a signal from second conductive line 202b through phase-change element 208 to first conductive line 202a. The signal passed to phase-change element 208 with CNT transistor 206 turned on is used to read the state of phase-change element 208, set phase-change element 208, or reset phase-change element 208. In response to a logic low signal on word line 204, CNT transistor 206 turns off to block signals from passing between first conductive line 202a and second conductive line 202b through phase-change element 208.

FIG. 3B is a diagram illustrating another embodiment of a memory cell 200b. In one embodiment, each memory cell 106a-106d is similar to memory cell 200b. Memory cell 200b is similar to memory cell 200a previously described and illustrated with reference to FIG. 3A, except that in memory cell 200b, second conductive line 202b is substantially perpendicular to first conductive line 202a and substantially parallel to word line 204. Memory cell 200b operates similarly to memory cell 200a.

In other embodiments, word line 204 is substantially parallel to first conductive line 202a and second conductive line 202b. In other embodiments, word line 204 is substantially parallel to first conductive line 202a and substantially perpendicular to second conductive line 202b. In other embodiments, other suitable configurations are used.

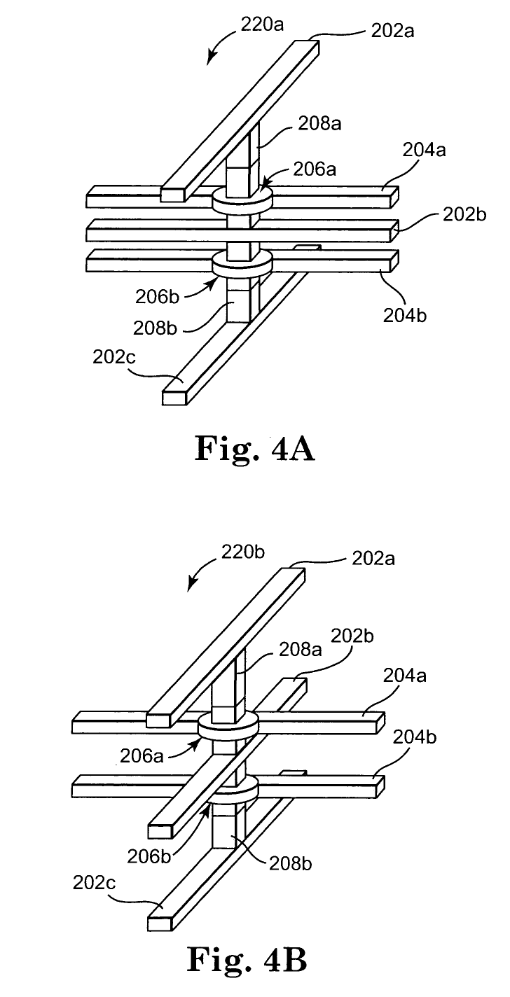

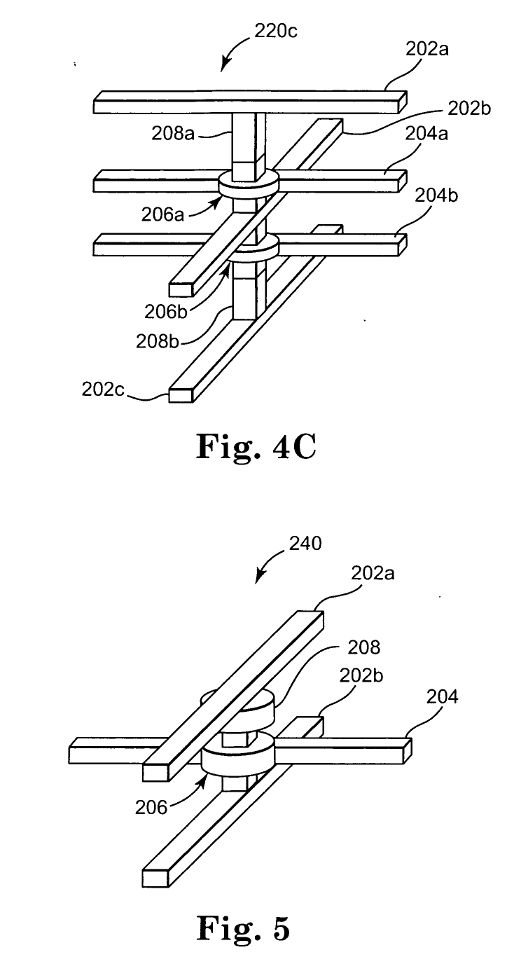

FIG. 4A is a diagram illustrating one embodiment of a pair of memory cells 220a. In one embodiment, each memory cell 106a-106d is similar to one of the memory cells in the pair of memory cells 220a. Memory cells 220a include a first conductive line 202a, a second conductive line 202b, a third conductive line 202c, a first word line 204a, a second word line 204b, a first CNT transistor 206a, a second CNT transistor 206b, a first phase-change element 208a, and a second phase-change element 208b.

First conductive line 202a is electrically coupled to one side of first phase-change element 208a. The other side of first phase-change element 208a is electrically coupled to one side of the source-drain path of first CNT transistor 206a. The other side of the source-drain path of first CNT transistor 206a is electrically coupled to second conductive line 202b. Second conductive line 202b is electrically coupled to one side of the source-drain path of second CNT transistor 206b. The other side of the source-drain path of second CNT transistor 206b is electrically coupled to one side of second phase-change element 208b. The other side of second phase-change element 208b is electrically coupled to third conductive line 202c. The gate of first CNT transistor 206a is electrically coupled to first word line 204a. The gate of second CNT transistor 206b is electrically coupled to second word line 204b.

In one embodiment, first conductive line 202a and third conductive line 202c are source lines and second conductive line 202b is a bit line. In another embodiment, first conductive line 202a and third conductive line 202c are bit lines and second conductive line 202b is a source line. First conductive line 202a is located in a first horizontal plane, first word line 204a is located in a second horizontal plane, second conductive line 202b is located in a third horizontal plane, second word line 204b is located in a fourth horizontal plane, and third conductive line 202c is located in a fifth horizontal plane. The first horizontal plane is spaced apart from and parallel to the second horizontal plane. The second horizontal plane is spaced apart from and parallel to the third horizontal plane. The third horizontal plane is spaced apart from and parallel to the fourth horizontal plane, and the fourth horizontal plane is spaced apart from and parallel to the fifth horizontal plane.

First phase-change element 208a extends from first conductive line 202a towards first word line 204a. The source-drain path of first CNT transistor 206a extends from first word line 204a toward first conductive line 202a and toward second conductive line 202b. The source-drain path of second CNT transistor 206b extends from second word line 204b toward second conductive line 202b and toward third conductive line 202c. Second phase-change element 208b extends from third conductive line 202c toward second word line 204b. First phase-change element 208a, the source-drain path of first CNT transistor 206a, the source-drain path of second CNT transistor 206b, and second phase-change element 208b are substantially aligned vertically.

In one embodiment, first conductive line 202a is substantially parallel to third conductive line 202c and substantially perpendicular to second conductive line 202b, first word line 204a, and second word line 204b. In another embodiment, second conductive line 202b, first word line 204a, and second word line 204b are at an angle other than 90° to first conductive line 202a and third conductive line 202c.

First phase-change element 208a is fabricated within the same via in which first CNT transistor 206a is fabricated. Second phase-change element 208b is fabricated within the same via in which second CNT transistor 206b is fabricated. First phase-change element 208a and second phase-change element 208b are made up of similar materials as phase-change element 208 previously described with reference to FIG. 3A.

In response to a logic high signal on first word line 204a, first CNT transistor 206a is turned on to pass a signal from first conductive line 202a through first phase-change element 208a to second conductive line 202b, or pass a signal from second conductive line 202b through first phase-change element 208a to first conductive line 202a. The signal passed to first phase-change element 208a with first CNT transistor 206a turned on is used to read the state of first phase-change element 208a, set first phase-change element 208a, or reset first phase-change element 208a. In response to a logic low signal on-first word line 204a, first CNT transistor 206a turns off to block signals from passing between first conductive line 202a and second conductive line 202b through first phase-change element 208a.

In response to a logic high signal on second word line 204b, second CNT transistor 206b is turned on to pass a signal from second conductive line 202b through second phase-change element 208b to third conductive line 202c, or pass a signal from third conductive line 202c through second phase-change element 208b to second conductive line 202b. The signal passed to second phase-change element 208b with second CNT transistor 206b turned on is used to read the state of second phase-change element 208b, set second phase-change element 208b, or reset second phase-change element 208b. In response to a logic low signal on second word line 204b, second CNT transistor 206b turns off to block signals from passing between second conductive line 202b and third conductive line 202c through second phase-change element 208b.

FIG. 4B is a diagram illustrating another embodiment of a pair of memory cells 220b. In one embodiment, each memory cell 106a-106d is similar to one of the memory cells in the pair of memory cells 220b. Memory cells 220b are similar to memory cells 220a previously described and illustrated with reference to FIG. 4A, except that in memory cells 220b, second conductive line 202b is substantially parallel to first conductive line 202a and third conductive line 202c and substantially perpendicular to first word line 204a and second word line 204b. Memory cells 220b operate similarly to memory cells 220a.

FIG. 4C is a diagram illustrating another embodiment of a pair of memory cells 220c. In one embodiment, each memory cell 106a-106d is similar to one of the memory cells in the pair of memory cells 220c. Memory cells 220c are similar to memory cells 220a previously described and illustrated with reference to FIG. 4A, except that in memory cells 220c, second conductive line 202b and third conductive line 202c are substantially perpendicular to first conductive line 202a. Memory cells 220c operate similarly to memory cells 220a.

In other embodiments, first word line 204a and second word line 204b are substantially parallel to first conductive line 202a, second conductive line 202b, and third conductive line 202c. In other embodiments, first word line 204a is substantially perpendicular to second word line 204b. In other embodiments, other suitable configurations are used FIG. 5 is a diagram illustrating another embodiment of a memory cell 240. In one embodiment, each memory cell 106a-106d is similar to memory cell 240. Memory cell 240 includes a first conductive line 202a, a second conductive line 202b, a word line 204, a CNT transistor 206, and a phase-change element 208. First conductive line 202a is electrically coupled to one side of phase-change element 208. The other side of phase-change element 208 is electrically coupled to one side of the source-drain path of CNT transistor 206. The other side of the source-drain path of CNT transistor 206 is electrically coupled to second conductive line 202b. The gate of CNT transistor 206 is electrically coupled to word line 204.

In one embodiment, first conductive line 202a is a source line and second conductive line 202b is a bit line. In another embodiment, first conductive line 202a is a bit line and second conductive line 202b is a source line. First conductive line 202a is located in a first horizontal plane, word line 204 is located in a second horizontal plane, and second conductive line 202b is located in a third horizontal plane. The first horizontal plane is spaced apart from and parallel to the second horizontal plane, and the second horizontal plane is spaced apart from and parallel to the third horizontal plane.

Phase-change element 208 extends from first conductive line 202a toward word line 204. The source-drain path of CNT transistor 206 extends from word line 204 toward first conductive line 202a and toward second conductive line 202b. Phase-change element 208 and the source-drain path of CNT transistor 206 are substantially aligned vertically.

In one embodiment, first conductive line 202a is substantially parallel to second conductive line 202b and substantially perpendicular to word line 204. In another embodiment, word line 204 is at an angle other than 90° to first conductive line 202a and second conductive line 202b. In other embodiments, other suitable configurations are used. Phase-change element 208 is fabricated in a mushroom configuration over a via in which CNT transistor 206 is fabricated. Memory cell 240 operates similarly to memory cell 200a previously described and illustrated with reference to FIG. 3A.

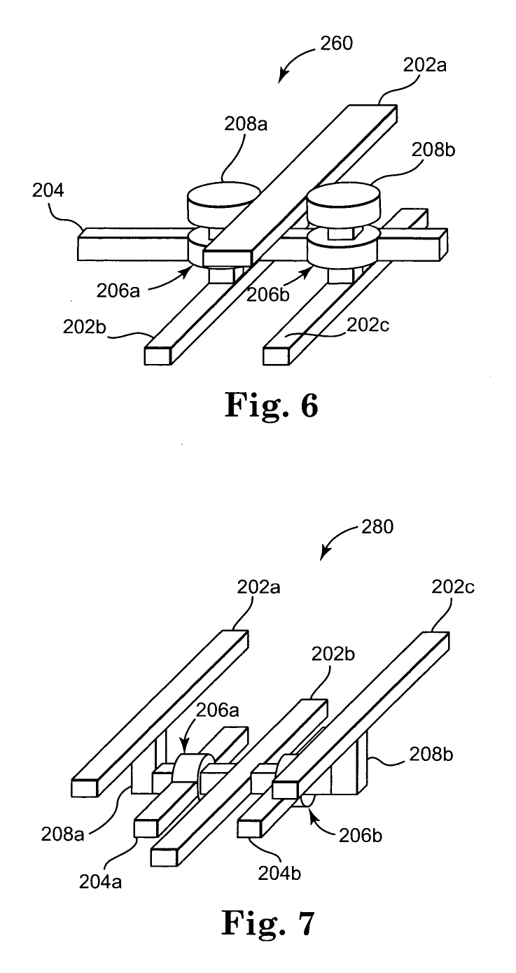

FIG. 6 is a diagram illustrating another embodiment of a pair of memory cells 260. In one embodiment, each memory cell 106a-106d is similar to one of the memory cells in the pair of memory cells 260. Memory cells 260 include a first conductive line 202a, a second conductive line 202b, a third conductive line 202c, a word line 204, a first CNT transistor 206a, a second CNT transistor 206b, a first phase-change element 208a, and a second phase-change element 208b.

First conductive line 202a is electrically coupled to a first side of first phase-change element 208a and a first side of second phase-change element 208b. A second side of phase-change element 208a substantially perpendicular to the first side of first phase-change element 208a is electrically coupled to one side of the source-drain path of first CNT transistor 206a. The other side of the source-drain path of first CNT transistor 206a is electrically coupled to second conductive line 202b. A second side of phase-change element 208b substantially perpendicular to the first side of second phase-change element 208a is electrically coupled to one side of the source-drain path of second CNT transistor 206b. The other side of the source-drain path of second CNT transistor 206b is electrically coupled to third conductive line 202c. The gate of first CNT transistor 206a and the gate of second CNT transistor 206b are electrically coupled to word line 204.

In one embodiment, first conductive line 202a is a source line and second conductive line 202b and third conductive line 202c are bit lines. In another embodiment, first conductive line 202a is a bit line and second conductive line 202a and third conductive line 202c are source lines. First conductive line 202a, first phase-change element 208a, and second phase-change element 208b are located in a first horizontal plane, word line 204 is located in a second horizontal plane, and second conductive line 202b and third conductive line 202c are located in a third horizontal plane. The first horizontal plane is spaced apart from and parallel to the second horizontal plane, and the second horizontal plane is spaced apart from and parallel to the third horizontal plane.

The source-drain path of first CNT transistor 206a extends from word line 204 toward first phase-change element 208a and toward second conductive line 202b. First phase-change element 208a and the source-drain path of first CNT transistor 206a are substantially aligned vertically. The source-drain path of second CNT transistor 206b extends from word line 204 toward second phase-change element 208b and toward third conductive line 202c. Second phase-change element 208b and the source-drain path of second CNT transistor 206b are substantially aligned vertically.

In one embodiment, first conductive line 202a is substantially parallel to second conductive line 202b and third conductive line 202c and substantially perpendicular to word line 204. In another embodiment, word line 204 is at an angle other than 90° to first conductive line 202a, second conductive line 202b, and third conductive line 202c. In other embodiments, other suitable configurations are used. First phase-change element 208a is fabricated in a mushroom configuration over a via in which first CNT transistor 206a is fabricated. Second phase-change element 208b is fabricated in a mushroom configuration over a via in which second CNT transistor 206b is fabricated.

In response to a logic high signal on word line 204, first CNT transistor 206a is turned on to pass a signal from first conductive line 202a through first phase-change element 208a to second conductive line 202b, or pass a signal from second conductive line 202b through first phase-change element 208a to first conductive line 202a. The signal passed to first phase-change element 208a with first CNT transistor 206a turned on is used to read the state of first phase-change element 208a, set first phase-change element 208a, or reset first phase-change element 208a. Also in response to a logic high signal on word line 204, second CNT transistor 206b is turned on to pass a signal from first conductive line 202a through second phase-change element 208b to third conductive line 202c, or pass a signal from third conductive line 202c through second phase-change element 208b to first conductive line 202a. The signal passed to second phase-change element 208b with second CNT transistor 206b turned on is used to read the state of second phase-change element 208b, set second phase-change element 208b, or reset second phase-change element 208b.

In response to a logic low signal on word line 204, first CNT transistor 206a turns off to block signals from passing between first conductive line 202a and second conductive line 202b through first phase-change element 208a. Also in response to a logic low signal on word line 204, second CNT transistor 206b turns off to block signals from passing between first conductive line 202a and third conductive line 202c through second phase-change element 208b.

FIG. 7 is a diagram illustrating another embodiment of a pair of memory cells 280. In one embodiment, each memory cell 106a-106d is similar to one of the memory cells in the pair of memory cells 280. Memory cells 280 include a first conductive line 202a, a second conductive line 202b, a third conductive line 202c, a first word line 204a, a second word line 204b, a first CNT transistor 206a, a second CNT transistor 206b, a first phase-change element 208a, and a second phase-change element 208b.

First conductive line 202a is electrically coupled to a first side of first phase-change element 208a. A second side of first phase-change element 208a substantially perpendicular to the first side of first phase-change element 208a is electrically coupled to one side of the source-drain path of first CNT transistor 206a. The other side of the source-drain path of first CNT transistor 206a is electrically coupled to second conductive line 202b. Second conductive line 202b is electrically coupled to one side of the source-drain path of second CNT transistor 206b. The other side of the source-drain path of second CNT transistor 206b is electrically coupled to a first side of second phase-change element 208b. A second side of second phase-change element 208b substantially perpendicular to the first side of second phase-change element 208b is electrically coupled to third conductive line 202c. The gate of first CNT transistor 206a is electrically coupled to first word line 204a. The gate of second CNT transistor 206b is electrically coupled to second word line 204b.

In one embodiment, first conductive line 202a and third conductive line 202c are source lines and second conductive line 202b is a bit line. In another embodiment, first conductive line 202a and third conductive line 202c are bit lines and second conductive line 202b is a source line. First conductive line 202a and second conductive line 202c are located in a first horizontal plane. Second conductive line 202b, first word line 204a, and second word line 204b are located in a second horizontal plane. The first horizontal plane is spaced apart from and parallel to the second horizontal plane.

First phase-change element 208a extends from first conductive line 202a to the second horizontal plane. The source-drain path of first CNT transistor 206a extends horizontally from word line 204b to first phase-change element 208a and to second conductive line 202b. Second phase-change element 208b extend from third conductive line 202c to the second horizontal plane. The source-drain path of second CNT transistor 206b extends horizontally from word line 204b to second phase-change element 208b and to second conductive line 202b. The source-drain path of first CNT transistor 206a and the source-drain path of second CNT transistor 206b are substantially aligned horizontally.

In one embodiment, first conductive line 202a and third conductive line 202c are substantially parallel to second conductive line 202b, first word line 204a, and second word line 204b. In another embodiment, first conductive line 202a and third conductive line 202c are at an angle to second conductive line 202b, first word line 204a, and second word line 204b. In other embodiments, other suitable configurations are used. Memory cells 280 operate similarly to memory cells 220a previously described and illustrated with reference to FIG. 4A.

Embodiments of the present invention provide memory cells including nanotube transistors for accessing memory elements. The nanotube transistor access devices have a higher current density than MOSFET access devices and enable the memory cell size to be scaled down to 4F². Many configurations for both stand alone memory circuits and embedded memory circuits are possible using the present invention.

What is claimed is:

1. A memory cell comprising:
a memory element; and
a nanotube transistor contacting the memory element for accessing the memory element.

2. The memory cell of claim 1, wherein the memory element comprises a phase-change memory element.

3. The memory cell of claim 1, wherein the memory element comprises a backend-of-line memory element.

4. The memory cell of claim 1, wherein the memory element is selected from a group consisting of a magneto-resistive memory element, a conductive bridging memory element, a ferro-electric memory element, a cantilever memory element, and a polymer memory element.

5. The memory cell of claim 1, wherein the nanotube transistor comprises a carbon nanotube (CNT) transistor.

6. A memory comprising:
a first conductive line;
a first memory element coupled to the first conductive line;
a first nanotube transistor having a source-drain path, a first side of the source-drain path contacting the first memory element;
a first word line coupled to a gate of the first nanotube transistor; and
a second conductive line coupled to a second side of the source-drain path of the first nanotube transistor.

7. The memory of claim 6, wherein applying a first signal on the first word line turns on the first nanotube transistor to pass a second signal between the first conductive line and the second conductive line to access the first memory element.

8. The memory of claim 6, wherein the word line is at an angle to the first conductive line and the second conductive line.

9. The memory of claim 6, wherein the word line is substantially parallel to one of the first conductive line and the second conductive line.

10. The memory of claim 6, further comprising:
a second nanotube transistor having a source-drain path, a first side of the source-drain path coupled to the second conductive line;
a second word line coupled to a gate of the second nanotube transistor;
a second memory element contacting a second side of the source-drain path of the second nanotube transistor; and
a third conductive line coupled to the second memory element.

11. The memory of claim 10, wherein the first conductive line is substantially parallel to the third conductive line and substantially perpendicular to the second conductive line.

12. The memory of claim 10, wherein the first conductive line is substantially perpendicular to the first word line and the second word line.

13. The memory of claim 10, wherein the first conductive line, the first word line, the second conductive line, the second word line, and the third conductive line are each located in different parallel planes.

14. The memory of claim 10, wherein the first conductive line and the third conductive line are located in a first plane, and wherein the first word line, the second conductive line, and the second word line are located in a second plane spaced apart from and parallel to the first plane.

15. A memory comprising:
a first conductive line;
a first memory element coupled to the first conductive line;
a first nanotube transistor having a source-drain path, a first side of the source-drain path contacting the first memory element;
a second conductive line coupled to a second side of the source-drain path of the first nanotube transistor;
a second memory element coupled to the first conductive line;
a second nanotube transistor having a source-drain path, a first side of the source-drain path contacting the second memory element;
a third conductive line coupled to a second side of the source-drain path of the second nanotube transistor; and
a word line coupled to a gate of the first nanotube transistor and a gate of the second nanotube transistor.

16. The memory of claim 15, wherein the word line is substantially perpendicular to the first conductive line.

17. The memory of claim 15, wherein the first conductive line, the first memory element, and the second memory element are located in the same plane.

18. The memory of claim 15, wherein the second conductive line and the third conductive line are located in the same plane.

19. A method for fabricating a memory, the method comprising:
providing a memory element; and
providing a nanotube transistor coupled to the memory element for accessing the memory element.

20. The method of claim 19, wherein providing the memory element comprises providing a phase-change memory element.

21. The method of claim 19, wherein providing the memory element comprises providing a backend-of-line memory element.

22. The method of claim 19, wherein providing the memory element comprises providing the memory element selected from a group consisting of a magneto-resistive memory element, a conductive bridging memory element, a ferro-electric memory element, a cantilever memory element, and a polymer memory element.

23. The method of claim 19, wherein providing the nanotube transistor comprises providing a carbon nanotube (CNT) transistor.

24. A method for fabricating a memory, the method comprising:
providing a first conductive line;
providing a first memory element coupled to the first conductive line;
providing a first nanotube transistor having a source-drain path, a first side of the source-drain path contacting the memory element;
providing a first word line coupled to a gate of the first nanotube transistor; and
providing a second conductive line coupled to a second side of the source-drain path of the first nanotube transistor.

25. The method of claim 24, wherein providing the first memory element comprises providing the first memory element in a same via in which the first nanotube transistor is provided.

26. The method of claim 24, wherein providing the first memory element comprises providing the first memory element in a mushroom configuration over a via in which the first nanotube transistor is provided.

27. The method of claim 24, further comprising:
providing a second nanotube transistor having a source-drain path, a first side of the source-drain path coupled to the second conductive line;
providing a second word line coupled to a gate of the second nanotube transistor;
providing a second memory element contacting a second side of the source-drain path of the second nanotube transistor; and
providing a third conductive line coupled to the second memory element.

28. A phase-change memory comprising:
a first conductive line;
a phase-change memory element coupled to the first conductive line;
a carbon nanotube transistor having a source-drain path, a first side of the source-drain path contacting the memory element;
a word line coupled to a gate of the nanotube transistor; and
a second conductive line coupled to a second side of the source-drain path of the nanotube transistor,
wherein applying a first signal on the word line turns on the nanotube transistor to pass a second signal between the first conductive line and the second conductive line to access the memory element.
